(19) United States
(12) Patent Application Publication
(10) Pub. No.: US 2012/0289020 A1
(43) Pub. Date: Nov. 15, 2012

(54) METHOD FOR FABRICATING VARIABLE RESISTANCE MEMORY DEVICE

(76) Inventors: Beom-Yong KIM, Gyeonggi-do (KR); Ki-Hong Lee, Gyeonggi-do (KR)

(21) Appl. No.: 13/330,639

(22) Filed: Dec. 19, 2011

(30) Foreign Application Priority Data
May 12, 2011 (KR) 10-2011-0044770

(51) Int. Cl. H01L 21/20

(52) U.S. Cl. 438/382; 257/E21.09

(57) ABSTRACT

A method for fabricating a variable resistance memory device includes forming a semiconductor pattern doped with impurities, forming a resistor over the semiconductor pattern, and forming a diode by performing microwave annealing to activate the impurities in the semiconductor pattern.

### CROSS-REFERENCE TO RELATED APPLICATIONS

The present application claims priority of Korean Patent Application No. 10-2011-0044770, filed on May 12, 2011, which is incorporated herein by reference in its entirety.

### BACKGROUND

1. Field

Exemplary embodiments of the present invention relate to a method of fabricating a variable resistance memory device, and more particularly, to a method of fabricating a variable resistance memory device including a diode as a selection element.

2. Description of the Related Art

A variable resistance memory device refers to a memory device that stores data using a resistor that has different resistance states depending on an applied bias. The resistor may include a transition metal oxide or perovskite-based material.

Such a variable resistance memory device may have a structure as described in FIG. 1 below.

FIG. 1 is a perspective view of a conventional variable resistance memory device.

Referring to FIG. 1, the conventional variable resistance memory device includes a plurality of first interconnections 110 positioned in parallel to each other and a plurality of second interconnections 140 positioned in parallel to each other and crossing the first interconnections 110. The first interconnections 110 are arranged in the lower portions of the variable resistance memory device, and the second interconnections 140 are arranged in the upper of the variable resistance memory device. The first and second interconnections 110 and 140 are spaced a designated distance from each other in a vertical direction.

A unit cell is disposed between the first and second interconnections 110 and 140. The unit cell includes a stacked structure of a diode 120 and a resistor 130. The diode 120 serves as a selection element of the cell, and the resistor 130 serves to store data.

When the structure of FIG. 1 is used, the unit cell may be formed at an intersection between the upper and lower interconnections. Therefore, the integration degree of the memory device may be increased. Furthermore, since a multi-stack structure including multiple layers stacked in a vertical direction may be implemented by the structure of FIG. 1, the integration degree may be further increased.

Meanwhile, the diode 120 used in the variable resistance memory device is generally formed by the following process. First, two or more amorphous silicon layers doped with different types of dopants are deposited. Next, a primary heat treatment that crystallizes silicon is performed, and a secondary heat treatment that activates the doped dopants is performed. The primary and secondary heat treatments are performed at a relatively high temperature. For example, the primary heat treatment for silicon crystallization is performed at 600° C. or more, and the second heat treatment for dopant activation is performed at 900° C. or more.

Meanwhile, since the resistor 130 used in the variable resistance memory device is relatively vulnerable to heat, a memory characteristic of the resistor 130 is destroyed at high temperature, for example, 500° C. or more.

Therefore, implementing the multi-stack structure where the structures of FIG. 1 are vertically stacked in a multilayer structure may be difficult. This difficulty is because the memory characteristic of a resistor is significantly damaged by a high-temperature heat treatment during a process that forms a second stack after the first stack is formed. Accordingly, the reliability of the variable resistance memory device may be significantly reduced.

Furthermore, the above-described diode formation process is repetitively performed whenever each stack is formed. More specifically, whenever each stack is formed, the silicon deposition process and the two heat treatments are performed to form a diode. Therefore, the process time required for fabricating the variable resistance memory device increases.

### SUMMARY

An embodiment of the present invention is directed to a method for fabricating a variable resistance memory device, which is capable of reducing a process time while enabling the fabrication of a variable resistance memory device that has high reliability and is highly integrated.

In accordance with an embodiment of the present invention, a method for fabricating a variable resistance memory device includes: forming a semiconductor pattern doped with impurities; forming a resistor over the semiconductor pattern; and forming a diode by performing microwave annealing to activate the impurities in the semiconductor pattern.

In accordance with another embodiment of the present invention, a method for fabricating a variable resistance memory includes: forming at least two stacks that are vertically stacked over a substrate, each stack includes a first interconnection extending in a first direction, a second interconnection extending in a second direction that crosses the first interconnection, and a stacked structure interposed between the first and second interconnections, wherein the stacked structure includes a diode semiconductor pattern and a resistor; and performing microwave annealing to activate impurities doped into the diode semiconductor patterns of the respective stacks.

### BRIEF DESCRIPTION OF THE DRAWINGS

FIG. 1 is a perspective view of a conventional variable resistance memory device.

FIG. 2 is a perspective view of a variable resistance memory device in accordance with an embodiment of the present invention.

FIGS. 3A to 3C are cross-sectional views illustrating a method for fabricating the variable resistance memory device of FIG. 2.

FIG. 4 is a graph illustrating a current-voltage characteristic of an NPN Zener diode used in the variable resistance memory device of FIG. 2.

FIG. 5 is a diagram illustrating the principle of microwave annealing.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

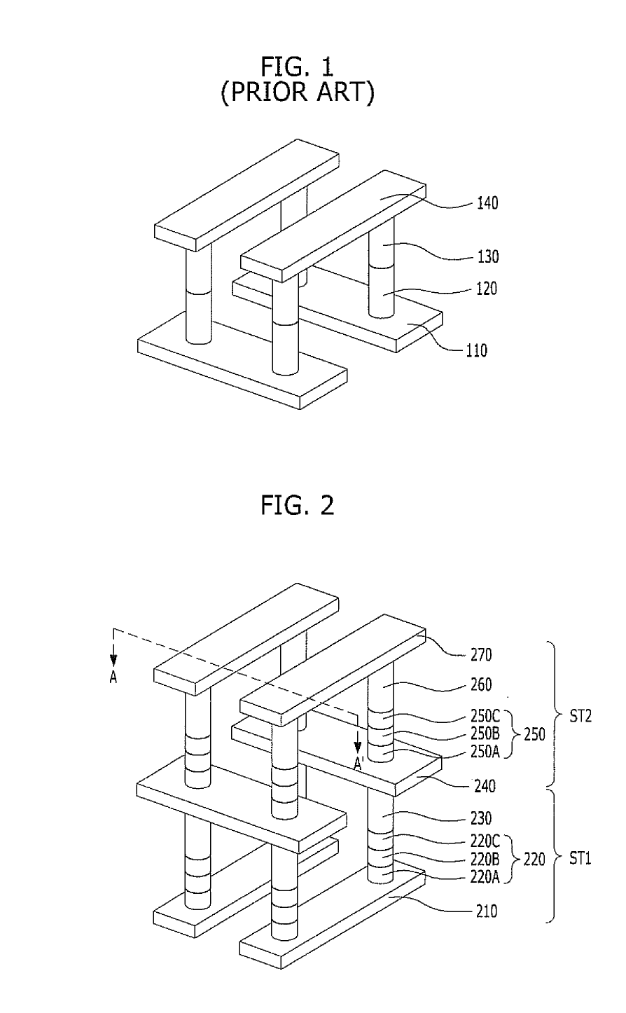

FIG. 2 is a perspective view of a variable resistance memory device in accordance with an embodiment of the present invention.

Referring to FIG. 2, the variable resistance memory device in accordance with the embodiment of the present invention includes one or more stacks each having a plurality of unit cells arranged in a matrix shape between upper and lower interconnections that cross each other.

In this embodiment of the present invention, a variable resistance memory device has a multi-stack structure including two stacks ST1 and ST2 that are vertically stacked. This structure is taken as an example for description, but the present invention is not limited thereto. The variable resistance memory device may include only one stack or three vertically stacked stacks.

The first stack ST1 includes a plurality of first interconnections 210 positioned in parallel to each other, a plurality of second interconnections 240 arranged over the first interconnections 210 and positioned in parallel to each other while crossing the first interconnections 210, and a unit cell arranged between the first and second interconnections 210 and 240. The unit cell has a stacked structure of a first diode 220 and a first resistor 230.

The first interconnections 210 are arranged over a substrate (not illustrated) having a designated lower structure, and may be formed of a metal such as aluminum (Al), tungsten (W), or copper (Cu).

The second interconnections 240 are arranged over the first interconnections 210 so as to be vertically spaced a designated distance from the first interconnections 210, and the second interconnections 240 may be formed of a metal such as Al, W, or Cu.

The first diode 220 serves as a selection element of the corresponding cell, and the first resistor 230 serves to store data in the corresponding cell.

The first diode 220 may include two or more semiconductor layers doped with different types of dopants. In this embodiment of the present invention, the first diode 220 may include an NPN diode having a P-type semiconductor layer 200B interposed between upper and lower N-type semiconductor layers 220A and 220C. Here, each of the upper and lower N-type semiconductor layers 220A and 200C may include a crystalline semiconductor such as polysilicon, which is doped with a high-concentration N-type dopant such as arsenic (As) or phosphorus (P), and the P-type semiconductor layer 220B may include a crystalline semiconductor such as polysilicon, which is doped with a high-concentration P-type dopant such as boron (B). The N-type and P-type dopants doped in the respective layers may have a concentration of 1,018/cm³ to 1,022/cm³.

Here, the first diode 220 may include an NPN Zener diode. In such an example, since the first diode 220 has a bipolar characteristic and a current has a symmetric characteristic toward the poles of a voltage source (refer to FIG. 4), the first diode 220 enables a high-speed operation of the variable resistance memory device in accordance with the embodiment of the present invention.

The first resistor 230 may include a material exhibiting one or more resistance states, which are discriminated from each other depending on an applied bias. For example, the first resistor 230 may be formed of a transition metal oxide such as NiO, TiO₂, HfO, Nb₂O₅, ZnO, ZrO₂, WO₃, or COO or a perovskite-based material such as STO (SiTiO), PCMO (PrCaMnO), or GST (GeSbTb).

Meanwhile, although not illustrated in the drawing, a barrier metal layer may be further interposed between the first interconnections 210 and the first diode 220 or between the first diode 220 and the first resistor 230. The barrier metal layer may include TaN, WN, WSiN, TaSiN, TiAl, TiAlN, TiN, and TiSiN, and the barrier metal layer may have a small thickness of 100 Å or less.

Over the first stack ST1 having the above-described structure, the second stack ST2 having substantially the same structure as the first stack ST1 may be disposed.

More specifically, the second stack ST2 includes the plurality of second interconnections 240 positioned in parallel to each other, a plurality of third interconnections 270 arranged over the second interconnections 240 and positioned in parallel to each other while crossing the second interconnections 240, and a unit cell arranged between the second and third interconnections 240 and 270. The unit cell includes a stacked structure of a second diode 250 and a second resistor 260.

The second diode 250 and the second resistor 260 may be formed of substantially the same materials as the first diode 220 and the first resistor 230, respectively. The second interconnections 240 may be used as common interconnections in the first and second stacks ST1 and ST2.

In this embodiment of the present invention, the variable resistance memory device includes, for example, only two stacks ST1 and ST2. As described above, however, a third stack (not illustrated), using the third interconnections 270 as common interconnections, may be formed over the second stack ST2. More specifically, a variable resistance memory device having a multi-stack structure including three or more stacks that are vertically stacked may be implemented. Furthermore, FIG. 2 illustrates that the first and second diodes 220 and 250 are arranged under the first and second resistors 230 and 260, respectively. However, the first and second diodes 220 and 250 may be arranged over the first and second resistors 230 and 260, respectively.

Hereafter, a method for fabricating the device of FIG. 2 will be described in detail.

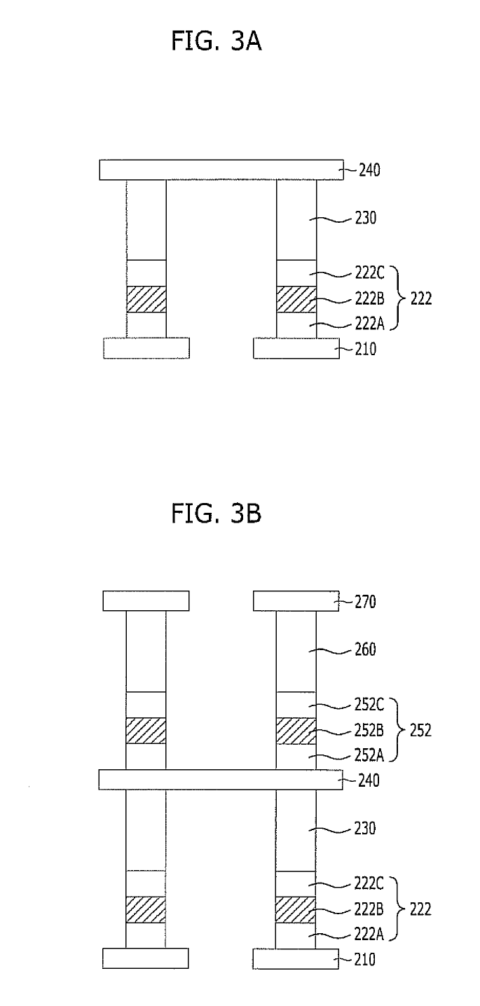

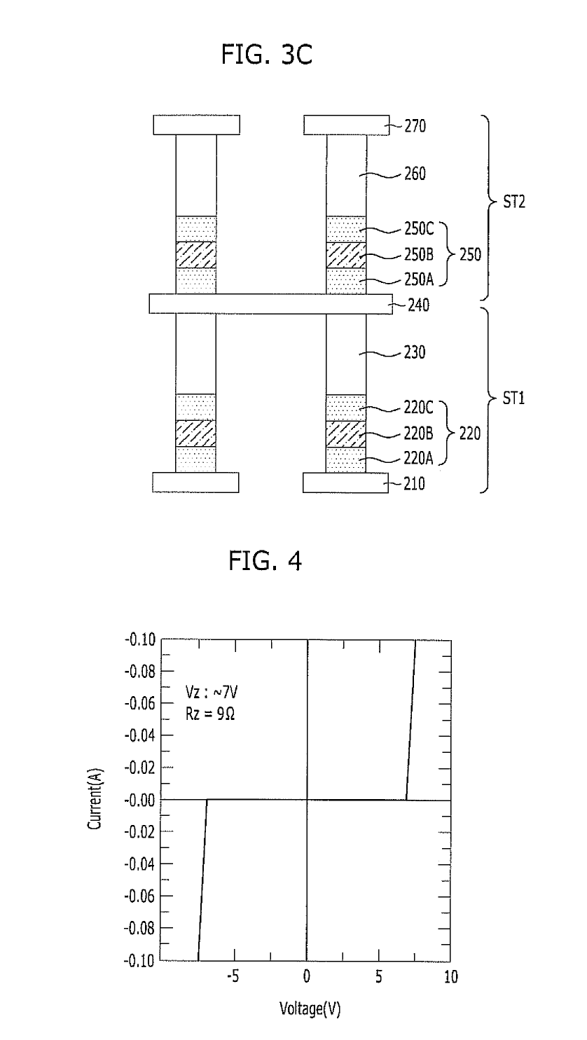

FIGS. 3A to 3C are cross-sectional views illustrating a method for fabricating the variable resistance memory device of FIG. 2, taken along a line A-A′ of FIG. 2.

Referring to FIG. 3A, a conductive layer such as a metal is deposited on a substrate (not illustrated) and subsequently patterned to form a plurality of first interconnections 210 extending in a first direction. Although not illustrated, an insulation layer may exist between the first interconnections 210.

An early first diode 222 is formed. The early first diode 222 includes an early lower N-type semiconductor layer 222A, an early P-type semiconductor layer 222B, and an early upper N-type semiconductor layer 222C, which are sequentially stacked.

Here, ‘early’ means a state immediately after a semiconductor material doped with a designated type of impurities is deposited. In this state, since a heat treatment is not yet performed, the doped impurities are not activated, but maintain an amorphous state. More specifically, the early lower and upper N-type semiconductor layers 222A and 222C may include an amorphous semiconductor material (for example, amorphous silicon) deactivated N-type dopant, and the early P-type semiconductor layer 222B may include an amorphous semiconductor material (for example, amorphous silicon) and an deactivated P-type dopant.

The early first diode 222 may be formed by the following process: an amorphous silicon layer doped with an N-type dopant, an amorphous silicon layer doped with a P-type dopant, and an amorphous silicon layer doped with an N-type dopant are successively deposited over the first interconnections 210 and subsequently etched in a pillar shape. More specifically, the depositing of the amorphous silicon layer doped with an N-type dopant, the amorphous silicon layer doped with a P-type dopant, and the amorphous silicon layer doped with an N-type dopant may be performed by in-situ doping a dopant while depositing amorphous silicon or doping a dopant through implantation after undoped amorphous silicon is deposited.

Meanwhile, although not illustrated, an insulation layer may exist between the early first diodes 222.

A first resistor 230 is formed over the early first diode 222.

The first resistor 230 may be formed by depositing a material used as the first resistor 230, for example, a transition metal oxide or perovskite-based material, over the early first diode 222 and then patterning the deposited material in a pillar shape. Meanwhile, although not illustrated, an insulation layer may exist between the first resistors 230.

A conductive layer such as a metal is deposited over the first resistor 230 and then patterned to form a plurality of second patterns extending in a second direction crossing the first interconnections 210. Meanwhile, although not illustrated, an insulation layer may exist between the second interconnections 240.

Through the above-described process, one stack structure may be formed. The process of FIG. 3A may be repeated to form another stack over the one stack.

For example, referring to FIG. 3B, substantially the same process as the above-described formation process of the early first diode 222 is performed to form an early second diode 252 over the second interconnections 240. The early second diode 252 overlaps the early first diode 222, and includes an early lower N-type semiconductor layer 252A, an early P-type semiconductor layer 252B, and an early N-type semiconductor layer 252C, which are sequentially stacked. Subsequently, substantially the same process as the above-described formation process of the first resistor 230 is performed to form a second resistor 260 over the early second diode 252. Subsequently, a plurality of third interconnections 270 extending in a direction crossing the second interconnections 230, for example, in the same direction as the first interconnections 210 are formed.

Through the above described process, a two-layer stack structure is formed.

The resultant structure of FIG. 3B may seem to have a similar structure to that of FIG. 2. However, since the early first and second diodes 222 and 252 include an amorphous semiconductor material and are in a state where the doped dopant is not activated, the early first and second diodes 222 and 252 do not function as a diode. Therefore, the following process of FIG. 3C is performed.

Referring to FIG. 3C, microwave annealing is performed on the resultant structure of FIG. 3B. As the microwave annealing process is performed, the early first and second diodes 222 and 252 are crystallized, and simultaneously, the doped dopant is activated, thereby forming final first and second diodes 220 and 250. Each of the first and second diodes 220 and 250 formed by the microwave annealing includes the upper and lower N-type semiconductor layers 220A and 220C and the P-type semiconductor layer 220B interposed between the upper and lower N-type semiconductor layers, and the upper and lower N-type semiconductor layers 220A and 220C and the P-type semiconductor layer 220B include a crystalline semiconductor material, for example, polysilicon and the activated N-type or P-type dopant.

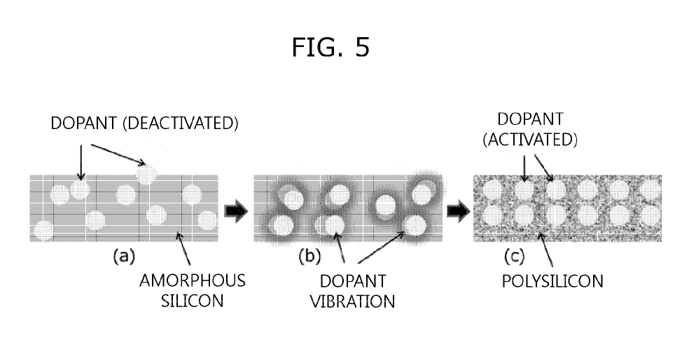

The principle of the microwave annealing will be described in more detail with reference to FIG. 5 below.

Referring to FIG. 5, an amorphous silicon layer doped with a designated type (N-type or P-type) of dopant is formed at step (a). At this time, the dopant is deactivated.

Subsequently, the microwave annealing is performed on the doped amorphous silicon layer at step (b). The microwave annealing may be performed at a relatively low temperature, for example, 500° C. or less.

During the microwave annealing, the dopant within the amorphous silicon layer is vibrated by a specific wavelength, and heat is simultaneously generated. While the dopant is activated by the heat, the amorphous silicon layer may be crystallized. Accordingly, a polysilicon layer having the activated dopant may be formed at step (c).

According to the principle of the microwave annealing, the crystallization and the dopant activation are simultaneously performed on the early first and second diodes 222 and 252 to form the final first and second diodes 220 and 250.

In the above-described method for fabricating a variable resistance memory device in accordance with the embodiment of the present invention, since the diode may be formed at a relatively low temperature, the memory characteristic of the resistor is not damaged despite the diode formation process. Therefore, a variable resistance memory device having a multi-stack structure without a reduction in reliability may be implemented. Accordingly, the high integration of the variable resistance memory device may also be achieved.

Furthermore, the crystallization of a semiconductor material that forms the diode and the dopant activation may be simultaneously performed through a microwave annealing process. Furthermore, when the variable resistance memory device has a multi-stack structure, the diode formation of all stacks may be completed by the microwave annealing process. Therefore, the process time to fabricate the variable resistance memory device may be reduced.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a variable resistance memory device, comprising:
forming a semiconductor pattern doped with impurities;
forming a resistor over the semiconductor pattern; and
forming a diode by performing microwave annealing to activate the impurities in the semiconductor pattern.

2. The method of claim 1, wherein the semiconductor pattern comprises an amorphous material, and
the microwave annealing is performed to crystallize the amorphous semiconductor pattern.

3. The method of claim 1, wherein the microwave annealing is performed at a temperature of 500° C. or less.

4. The method of claim 1, wherein the semiconductor pattern comprises a silicon pattern.

5. The method of claim 1, wherein the semiconductor pattern is a stacked structure including an N-type layer, a P-type layer, and an N-type layer.

6. The method of claim 1, further comprising:
forming a first interconnection extending in a first direction; and
forming a second interconnection extending in a second direction that crosses the first direction,
wherein the semiconductor pattern and the resistor are disposed between the first and second interconnections.

7. The method of claim 6, wherein the microwave annealing is performed after the forming of the first and second interconnections,

8. A method for fabricating a variable resistance memory, comprising:
forming at least two stacks that are vertically stacked over a substrate, each stack includes a first interconnection extending in a first direction, a second interconnection extending in a second direction that crosses the first interconnection, and a stacked structure interposed between the first and second interconnections, wherein the stacked structure includes a diode semiconductor pattern and a resistor; and
performing microwave annealing to activate impurities doped into the diode semiconductor patterns of the respective stacks,

9. The method of claim 8, wherein the semiconductor pattern comprises an amorphous material, and
the microwave annealing is performed to simultaneously crystallize the amorphous semiconductor pattern while activating impurities doped into the diode semiconductor patterns of the respective stacks.

10. The method of claim 8, wherein the microwave annealing is performed at a temperature of 500° C. or less.

11. The method of claim 8, wherein the semiconductor pattern comprises a silicon pattern.

12. The method of claim 8, wherein the semiconductor pattern is a stacked structure including an N-type layer, a P-type layer, and an N-type layer.

13. The method of claim 8, wherein each of the stacks comprises a plurality of first interconnections and a plurality of second interconnections, and
the stacked structure of the semiconductor pattern and the resistor is disposed at each intersection between the first and second interconnections.

14. The method of claim 13, further comprising:
forming an insulation layer between the plurality of first interconnections, the plurality of second interconnections, and the plurality of stacked structures.

15. The method of claim 8, wherein the diode semiconductor pattern is an NPN Zener diode after performing the microwave annealing.

16. The method of claim 8, wherein the impurities doped in the diode semiconductor patterns is doped at a concentration of 1,018/cm³ to 1,022/cm³.
